(19) United States
(12) Patent Application Publication
(10) Pub. No.: US 2025/0389497 A1
(43) Pub. Date: Dec. 25, 2025

(54) FAN WITH MAGNETIC SUCTION SUPPORT

(71) Applicant: GUANGDONG TCOMAS TECHNOLOGY CO., LTD, Huizhou (CN)

(72) Inventor: Zhenzhi Liang, Huizhou (CN)

(21) Appl. No.: 18/753,913

(22) Filed: Jun. 25, 2024

(30) Foreign Application Priority Data
May 4, 2023 (CN) 202321044172.X

(51) Int. Cl. F28F 9/007; H05K 7/20

(52) U.S. Cl. CPC F28F 9/007; F28F 2250/08; F28F 2275/22; H05K 7/20172

(57) ABSTRACT

Disclosed is a fan with a magnetic suction support, including at least one fan, a support and a water-cooled row. The fan is arranged with at least one fan magnetic suction structure, and the support is arranged with the same number of support magnetic suction structures matched with the fan magnetic suction structure. By the above technical solution, the fan can be easily opened and closed, a radiator can be easily cleaned, the fan can be easily disassembled and mounted only by tilting the fan when assembling and disassembling, and the fan can be well fixed on the support by the cooperation of the magnetic suction structure and fastener structures when closed, with the advantages of quick and easy assembly and disassembly and simple structure.

### CROSS-REFERENCE TO RELATED APPLICATIONS

This application claims priority of Chinese Patent Application No. 202321044172.X, filed on May 4, 2023, the entire contents of which are incorporated herein by reference.

### TECHNICAL FIELD

The present disclosure relates to the field of radiators, and specifically relates to a fan with a magnetic suction support.

### BACKGROUND

A radiator is a device used to conduct and release heat, which is often used in computer equipment, mechanical equipment and heating equipment. The equipment generates a large amount of heat when working. If the equipment cannot be cooled down in time, it is likely to destroy the working equipment. In this case, it is necessary to quickly dissipate heat through the radiator to avoid aggregation, ensuring the normal operation of equipment.

Today's computer systems have more and more powerful computing power, while generating more and more heat. To meet the increasing demand for heat dissipation, water-cooled heat dissipation systems with better heat dissipation are proposed.

In the prior art, a fan is mounted on some water-cooled heat dissipation systems, and the fan on the existing water-cooled radiator is fixed by means of a nut or an adhesive, and is additionally connected to a wire. When a user needs to perform operations such as replacing the fan, adding or reducing the fan, and cleaning dust of the radiator, it is very inconvenient to disassemble and assemble the fan, and it is not only required to unscramble the wire, but also required to use an additional tool such as a screwdriver to assist the disassembly and assembly, thus greatly affecting the user's experience.

### SUMMARY

An object of the present disclosure is to provide a fan with a magnetic suction support to overcome the deficiencies in the prior art.

The object of the present disclosure is achieved by the following technical solutions.

A fan with a magnetic suction support includes at least one fan, a support and a water-cooled row. A radiator is a water-cooled radiator; the water-cooled row stores water-cooled liquid; and the fan cools the water-cooled liquid more quickly. The support is fixedly connected above the water-cooled row, and a size of a rectangular plane of the support is consistent with that of the water-cooled row, to achieve better fitting and improve the utilization rate of space. The fan is movably connected above the support, and the fan and the support are obliquely opened and closed, and replaced conveniently; and the fan is arranged with at least one fan magnetic suction structure, the fan magnetic suction structure being a magnet or a strong magnetic material, and being mutually attracted with a support magnetic suction structure to achieve the function of movably fixing the fan. The support is arranged with the same number of support magnetic suction structures matched with the fan magnetic suction structure, the support magnetic suction structure being a magnet or a strong magnetic material, and being mutually attracted with the fan magnetic suction structure to achieve the function of movably fixing the fan. A position of the support magnetic suction structure corresponds to that of the fan magnetic suction structure; and the position matching makes the magnetic suction stronger and saves the magnetic suction material used.

In one example, the fan magnetic suction structure is a magnet with a strong magnetic material magnetically attracted; and the support magnetic suction structure is a strong magnetic material, and the strong magnetic material can be attracted by a magnetic object, so that the support magnetic suction structure can be attracted by the fan magnetic suction structure, to achieve the function of movable connection between the fan and the support.

In one example, the fan magnetic suction structure is a strong magnetic material, and the strong magnetic material can be attracted by an object with magnetism; and the support magnetic suction structure is a magnet, and the magnet with magnetism can attract the strong magnetic material. Therefore the fan magnetic suction structure can be attracted by the support magnetic suction structure, to achieve the function of movable connection between the fan and the support.

In one example, the support is formed by combining an upper support and a lower support, a shape of the upper support matches with that of the lower support, and there is a corresponding position of a limiting hole inside. The support magnetic suction structure is fixed on the lower support by means of pasting, nut, convex limiting, etc. The upper support has upper support magnetic suction holes matched with the support magnetic suction structure in shape and position, and the support magnetic suction structure can just pass through the upper support magnetic suction holes; and the support magnetic suction structure penetrates through the upper support magnetic suction hole when the upper support is combined with the lower support. After penetrating through the upper support magnetic suction holes, the support magnetic suction structure exposes the upper surface thereof in the combined support, and is attracted by the fan magnetic suction structure.

In one example, the support magnetic suction structure is a convex-shaped sheet, the convex-shaped design is pressed and fixed by the upper support in combination with the protrusion of the lower support, and the sheet design saves material; and the support is a hollow rectangular structure, and the hollow rectangular design allows a space for the air flow between the water-cooled row and the fan to achieve the heat dissipation function.

In one example, the support is disposed with at least four support screw holes, the four support screw holes are located on four corners of the support, and when the number is greater than four, the screw holes are located on a side with a longer length, to shorten the distance between fixing screws to achieve better fixing. The water-cooled row is disposed with water-cooled row screw holes corresponding to the support screw holes, two screw holes corresponding in position can be connected together by the same screw, the support is arranged with support screws, the support screws are used for connecting the support and the water-cooled row, and the support screws penetrate through the support screw holes and are fixed on the water-cooled row screw holes. The fixed connection between the support and the water-cooled row is achieved by connecting the support screw holes and the water-cooled row screw holes via the same screw.

In one example, the fan includes a fan base and a fan surface cover, the fan base and the fan surface cover are fixedly connected by screws, the fan magnetic suction structure is fixed on the fan surface cover, the fan magnetic suction structure is a cylindrical structure inside the fan surface cover, the fan base has fan base magnetic suction holes matched with the fan magnetic suction structures in in shape and position, the fan magnetic suction structure can just pass through the fan base magnetic suction hole, and when the fan base and the fan surface cover are combined, the fan magnetic suction structure penetrates through the fan base magnetic suction hole. After penetrating through the fan base magnetic suction holes, the fan magnetic suction structure exposes the lower surface thereof in the combined fan, and is mutually attracted by the support magnetic suction structure.

In one example, the support is arranged with an electro-conductive interface, the electro-conductive interface providing power to the fan, the support is arranged with at least one support electro-conductive contact, the support electro-conductive contact is connected to the fan, the fan is arranged with a fan electro-conductive contact matched with the support electro-conductive contact, and the fan electro-conductive contact cooperates with the support electro-conductive contact to achieve electrical signal conduction.

In one example, the support is arranged with integrally formed L-shaped support fasteners, and the support fastener is an L-shaped protrusion integrally formed with the support. There are at least two support fasteners, the fan is disposed with fan fastener holes matched with the support fastener, the fan fastener hole corresponds to a shape of the support fastener, the fan fastener hole is obliquely inserted into the support fastener to achieve the movable fastener connection between the fan and the support, and the fan and the support can be opened and closed in one direction.

The present disclosure has the following advantageous effect.

In the present disclosure, due to the use of the above technical solutions, it is very convenient to open and close the fan and clean the radiator. When it needs to be disassembled, the fan can be directly taken down by opening to a certain angle, which is convenient to replace, and increase or decrease the radiator; and when the fan is closed, the fan can be well fixed on the support through the cooperation of the magnetic suction structure and the fastener structure, and the fan electro-conductive contact is attached to the support electro-conductive contact to achieve telecommunication connection, so that the fan does not need additional wire power supply control and power supply port, and has the advantages of quick and easy disassembly and assembly and simple structure.

### BRIEF DESCRIPTION OF THE DRAWINGS

In order to explain the technical solution of the present disclosure more clearly, brief descriptions are given below of the accompanying drawings which are required to be used in the present disclosure. It is to be understood that the following drawings illustrate only some examples of the present disclosure, and therefore, the examples are not considered as limiting the scope. Other related accompanying drawings can be obtained according to the drawings without creative efforts for those of ordinary skill in the art.

FIG. 1 is an exploded view I of the present disclosure.

FIG. 2 is an exploded view II of the present disclosure.

FIG. 3 is a partial perspective view I of the present disclosure.

FIG. 4 is a partial perspective view II of the present disclosure.

FIG. 5 is a partial perspective view III of the present disclosure.

FIG. 6 is an enlarged view at A of FIG. 5.

FIG. 7 is a front view of the present disclosure.

FIG. 8 is a top view of the present disclosure.

FIG. 9 is a bottom view of the present disclosure.

Reference numerals and denotations thereof: 1—fan, 2—support, 3—water-cooled row, 4—electro-conductive interface, 11—fan magnetic suction structure, 12—fan surface cover, 13—fan base, 14—fan base magnetic suction hole, 15—fan electro-conductive contact, 16—fan fastener hole, 21—support magnetic suction structure, 22—lower support, 23—upper support, 24—upper support magnetic suction hole, 26—support screw hole, 27—support screw, 28—support electro-conductive contact, 29—support fastener, and 31—water-cooled row screw hole.

### DETAILED DESCRIPTION

To facilitate the understanding of the present disclosure, the present disclosure is described more comprehensively with reference to related accompanying drawings. Preferred implementations of the present disclosure are shown in the accompanying drawings. However, the present disclosure can be implemented in many different forms and is not limited to implementations described herein. On the contrary, these implementations are provided for a more thorough and comprehensive understanding of the disclosure of the present disclosure.

It is to be noted that when an element is said to be “fixed” to another element, it can be directly fixed to another element or fixed to an element therebetween. When an element is considered to be “connected” to another element, it can be directly connected to another element or connected to an element therebetween. The terms “vertical”, “horizontal”, “left”, “right” and similar expressions used herein are for illustrative only, and do not represent the only implementation.

Unless otherwise defined, all technical and scientific terms used herein have the same meaning as commonly understood by those skilled in the technical field of the present disclosure. The terms used herein in the specification of the present disclosure are only for describing specific implementations, and are not intended to limit the present disclosure. The term “and/or” used herein includes any and all combinations of one or more of related listed items.

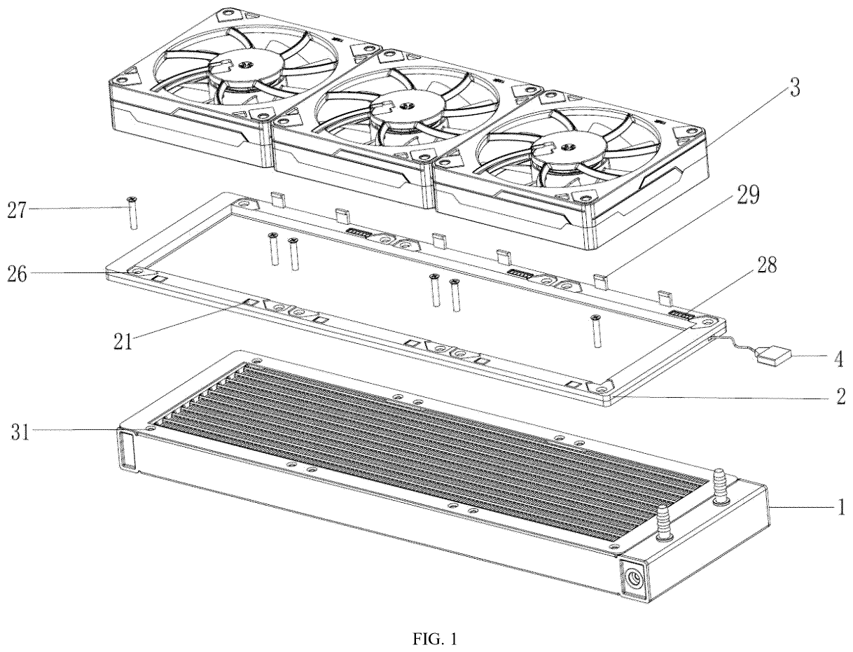

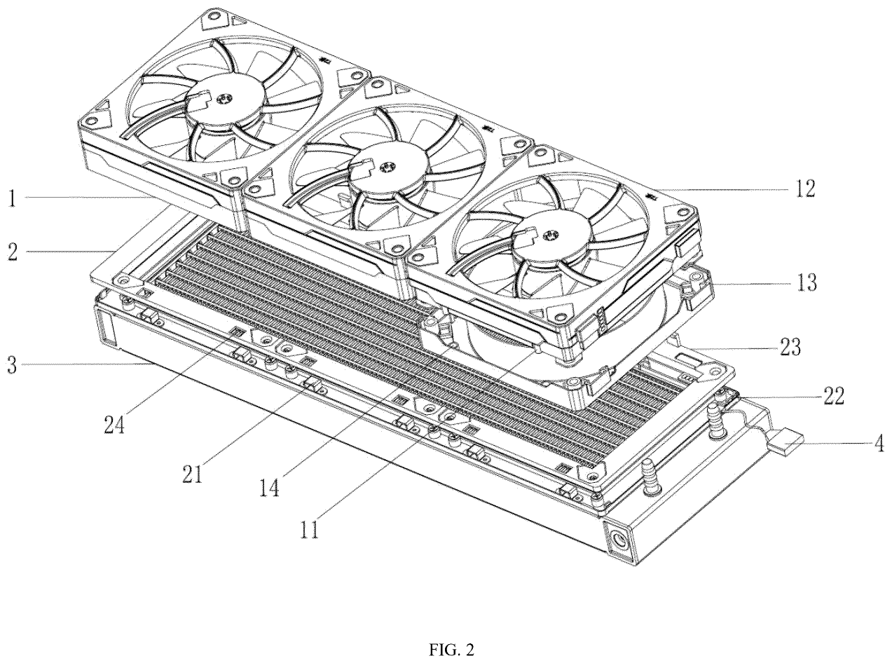

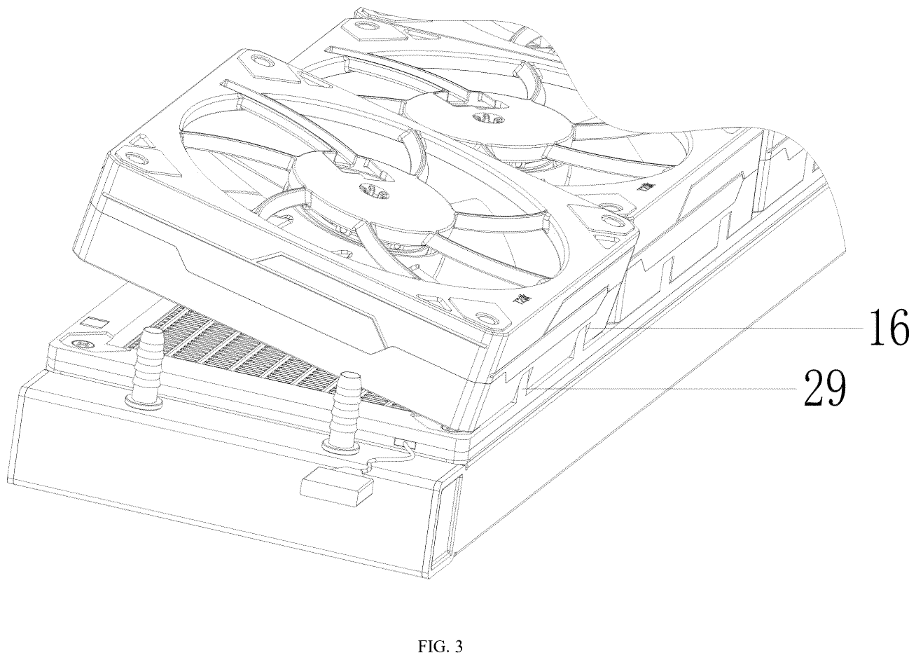

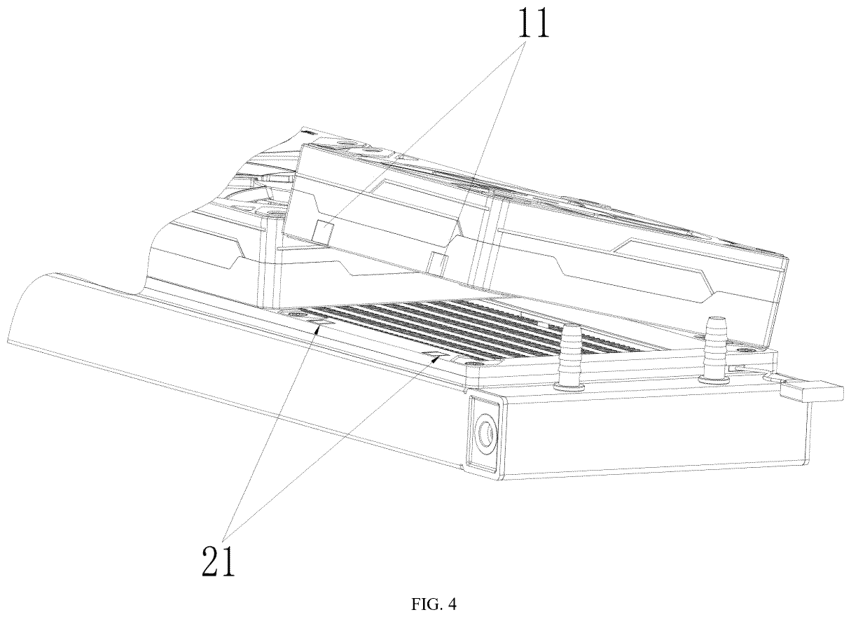

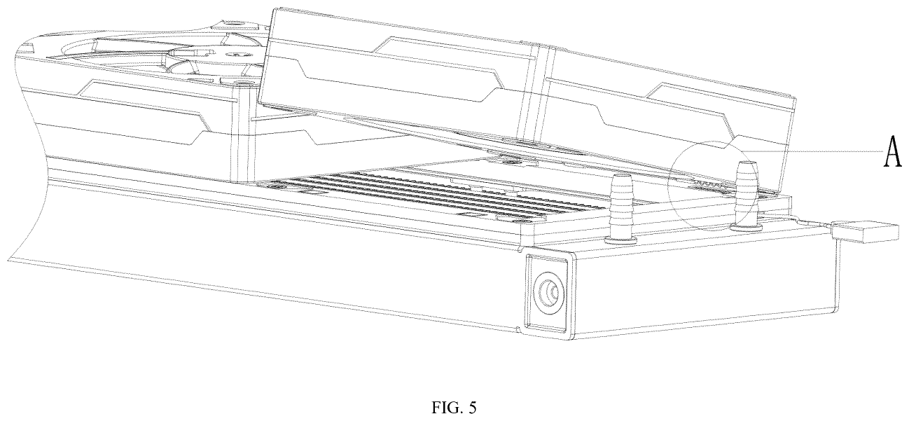

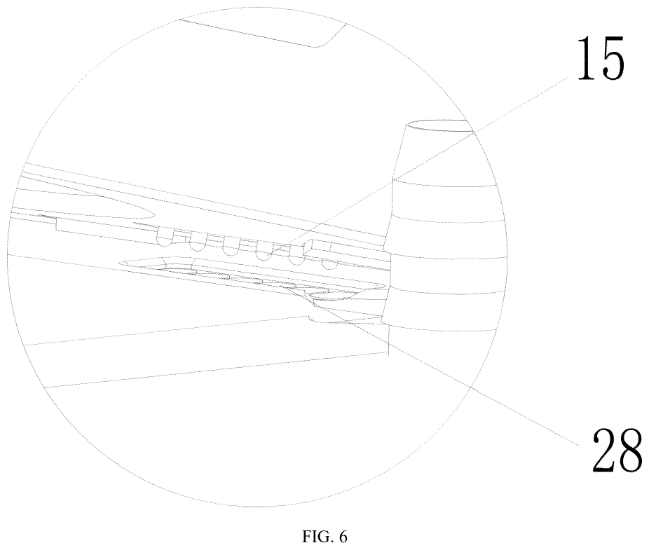

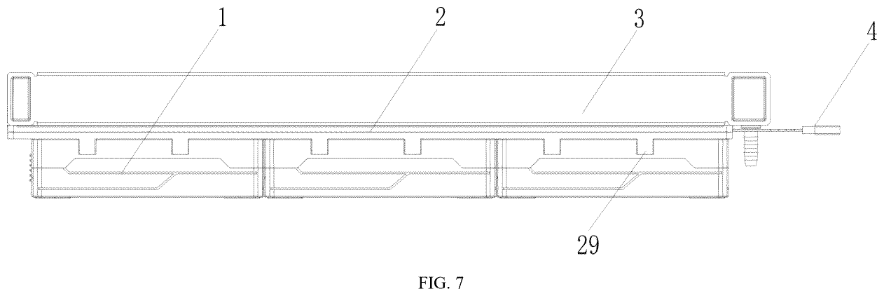

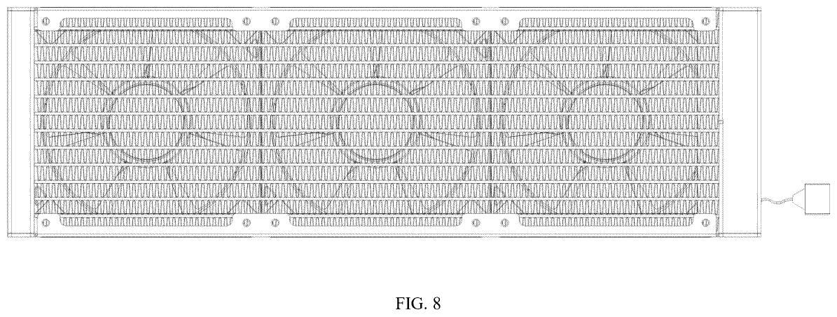

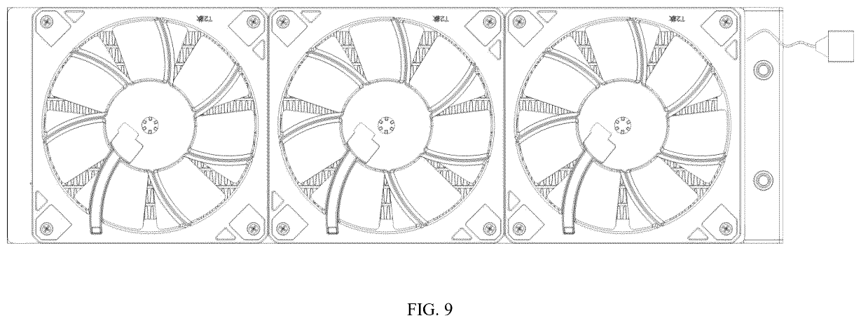

Reference is made to FIGS. 1-9 for examples of the present disclosure.

A fan with a magnetic suction support includes at least one fan 1, a support 2 and a water-cooled row 3. The support 2 is fixedly connected above the water-cooled row 3, the fan 1 is movably connected above the support 2, the fan 1 is arranged with at least one fan magnetic suction structure 11, the support 2 is arranged with the same number of support magnetic suction structures 21 matched with the fan magnetic suction structure 11, and a position of the support magnetic suction structure 21 corresponds to that of the fan magnetic suction structure 11.

By adopting the above technical solution, a radiator is a water-cooling radiator composed of a fan 1, a support 2 and a water-cooled row 3. The water-cooled row 3 stores water-cooling liquid, the support 2 is fixedly connected above the water-cooled row 3, and the fan 1 is movably connected above the support 2. After the fan 1 is started, the air circulation above the water-cooled row 3 is accelerated to cool the water-cooling liquid quickly. A shape of the support 2 is consistent with that of the water-cooled row 3, which can better fit and improve the utilization rate of space. The fan 1 is obliquely inserted into the support 2 to achieve the movable connection, and only needs to be obliquely taken down during disassembly, which is very convenient. The fan magnetic suction structure 11 is made of a magnet or a strong magnetic material, and mutually attracted with the support magnetic suction structure 21 to achieve the function of movably fixing the fan 1. The support 2 is arranged with the same number of support magnetic suction structures 21 as the fan magnetic suction structure 11; and the support magnetic suction structure 21 is made of a magnet or a strong magnetic material, and mutually attracted with the fan magnetic suction structure 11 to achieve the function of movably fixing the fan 1. The positions of the support magnetic suction structure 21 and the fan magnetic suction structure 11 correspond to each other; and the position correspondence and fit makes the magnetic suction stronger, which can save the used magnetic suction materials and reduce the influence on the outside world.

Preferably, the fan magnetic suction structure 11 is a magnet, and the support magnetic suction structure 21 is a strong magnetic material.

By adopting the above technical solution, the strong magnetic material can be attracted by a magnet with magnetism, and the strong magnetic material can be attracted by an object with magnetism; therefore, the support magnetic suction structure 21 can be attracted by the fan magnetic suction structure 11, to achieve the fixation between the fan 1 and the support 2, and the convenient opening and closing without additional operations.

Preferably, the fan magnetic suction structure 11 is a strong magnetic material, and the support magnetic suction structure 21 is a magnet.

By adopting the above technical solution, the strong magnetic material can be attracted by an object with magnetism, and the magnet with magnetism can attract the strong magnetic material; therefore, the fan magnetic suction structure 11 can be attracted by the support magnetic suction structure 21, to achieve the fixation between the fan 1 and the support 2, and the convenient opening and closing without additional operations.

Preferably, the support 2 is formed by combining an upper support 23 and a lower support 22, the support magnetic suction structure 21 is fixed on the lower support 22, the upper support 23 has upper support magnetic suction holes 24 matched with the support magnetic suction structures 21 in shape and position, and the support magnetic suction structure 21 penetrates through the upper support magnetic suction hole 24 when the upper support 23 and the lower support 22 are combined.

By adopting the above technical solution, the upper support 23 and the lower support 22 are matched in shape and have corresponding limiting hole positions therein, so that the upper support 23 and lower support 22 can be stably combined into the support 2. The support magnetic suction structure 21 is fixed on the lower support 22 by means of pasting, nut, convex limiting, etc.; the upper support 23 has upper support magnetic suction holes 24 matched with the support magnetic suction structures 21 in shape and position, and the support magnetic suction structure 21 can just pass through the upper support magnetic suction hole 24; and the support magnetic suction structure 21 penetrates through the upper support magnetic suction hole 24 when the upper support 23 is combined with the lower support 22. After penetrating through the upper support magnetic suction holes 24, the support magnetic suction structure 21 exposes the upper surface thereof in the combined support 2, and is attracted by the fan magnetic suction structure.

Preferably, the support magnetic suction structure 21 is a convex-shaped sheet, and the support 2 is a hollow rectangular structure.

By adopting the above technical solution, the convex-shaped design is matched with a rectangular protrusion of the lower support 22, and when the upper support 23 and the lower support 22 are combined, the upper support 23 presses against the protrusion to achieve fixation, and the sheet design saves material; and a hollow rectangular design of the support 2 allows a space for the air flow between the water-cooled row 3 and the fan 1 to achieve the heat dissipation function.

Preferably, the support 2 is disposed with at least four support screw holes 26, the water-cooled row 3 is disposed with water-cooled row screw holes 31 corresponding to the support screw holes 26, the support 2 is arranged with support screws 27, and the support screws 27 penetrate through the support screw holes 26 and are fixed on the water-cooled row screw holes 31.

By adopting the above technical solution, the four support screw holes 26 disposed by the support 2 are located on four corners of the support 2, and when the number is greater than four, the screw holes are located on a side with a longer length, to shorten the distance between fixing screws to improve stability. The water-cooled row screw holes 31 disposed by the water-cooled row 3 corresponding to positions of the support screw holes 26 can be connected together by the same screw, the support 2 is used for connecting the support 2 and the water-cooled row 3 through the support screws 27, and the support screws 27 penetrate through the support screw holes 26 and are fixed on the water-cooled row screw holes 31. The fixed connection between the support 2 and the water-cooled row 3 is achieved by connecting the support screw holes 26 and the water-cooled row screw holes 31 via the same screw.

Preferably, the fan 1 includes a fan base 13 and a fan surface cover 12, the fan magnetic suction structures 11 are fixed on the fan surface cover 12, the fan base 13 has fan base magnetic suction holes 14 matched with the fan magnetic suction structures 11 in shape and position, and the fan magnetic suction structure 11 penetrates through the fan base magnetic suction hole 14 when the fan base 13 and the fan surface cover 12 are combined.

By adopting the above technical solution, the fan base 13 and the fan surface cover 12 are fixedly connected by screws, the fan magnetic suction structure 11 is a cylindrical structure fixed inside the fan surface cover 12, the fan base 13 has fan base magnetic suction holes 14 matched with the fan magnetic suction structures 11 in shape and position, the fan magnetic suction structure 11 can just pass through the fan base magnetic suction hole 14, and when the fan base 13 and the fan surface cover 12 are combined, the fan magnetic suction structure 11 penetrates through the fan base magnetic suction hole 14 and then exposes the lower surface, to mutually attract with the support magnetic suction structure 21.

Preferably, the support 2 is arranged with an electro-conductive interface 4, the support 2 is arranged with at least one support electro-conductive contact 28, and the fan 1 is arranged with a fan electro-conductive contact 15 matched with the support electro-conductive contact 28.

By adopting the above technical solution, the electro-conductive interface 4 provides power for the fan 1, the support electro-conductive contact 28 arranged on the support 2 can communicate with the fan 1, the fan 1 is arranged with the fan electro-conductive contact 15 matched with the support electro-conductive contact 28, and the fan electro-conductive contact 15 and the support electro-conductive contact 28 cooperate to achieve electrical signal conduction.

Preferably, the support 2 is arranged with integrally formed L-shaped support fasteners 29, and the fan 1 is disposed with fan fastener holes 16 matched with the support fasteners 29.

By adopting the above technical solution, the support fastener 29 is an L-shaped protrusion integrally formed with the support 2. There are at least two support fasteners 29, the fan fastener hole 16 on the fan 1 is matched with the support fastener 29 in shape and corresponds to the support fastener 29 in position, the fan fastener hole 16 is obliquely inserted into the support fastener 29 to achieve the movable fastener connection between the fan 1 and the support 2, and the fan 1 and the support 2 can be opened and closed in one direction.

The working principle is as follows. By using the mutual attraction property of the magnet and the strong magnetic material, the fan 1 is fixed on the support 2 and is very easy to be disassembled and assembled, and the support fasteners 29 and the fan fastener holes 16 achieve the movable fastener connection to achieve one-way opening and closing of the fan 1, and finally the fan 1 is controlled to operate by electrically connecting the fan electro-conductive contact 15 and the support electro-conductive contact 28.

During mounting, the fan fastener holes 16 on the fan 1 of the present disclosure are obliquely inserted into the support fasteners 29 at corresponding positions, the fan 1 is closed and laid flat, the radiator of the present disclosure is placed at a heating point requiring heat dissipation and fixed, and finally the electro-conductive interface 4 is connected to a power source hole position corresponding to a main board to complete the mounting.

The above examples only express several implementations of the present disclosure, and are described more specifically and in detailed, but which cannot be understood as limiting the scope of the present disclosure. It is to be pointed out that for those ordinary skilled in the art, without departing from the concept of the present disclosure, several modifications and improvements can be made, which are within the scope of protection of the present disclosure. Therefore, the scope of protection of the present disclosure is subject to the appended claims.

1. A fan with a magnetic suction support, comprising at least one fan (1), a support (2) and a water-cooled row (3), wherein the support (2) is fixedly connected above the water-cooled row (3), the fan (1) is movably connected above the support (2), the fan (1) is arranged with at least one fan magnetic suction structure (11), the support (2) is arranged with the same number of support magnetic suction structures (21) matched with the fan magnetic suction structure (11), and a position of the support magnetic suction structure (21) corresponds to that of the fan magnetic suction structure (11).

2. The fan with a magnetic suction support according to claim 1, wherein the fan magnetic suction structure (11) is a magnet, and the support magnetic suction structure (21) is a strong magnetic material.

3. The fan with a magnetic suction support according to claim 1, wherein the fan magnetic suction structure (11) is a strong magnetic material, and the support magnetic suction structure (21) is a magnet.

4. The fan with a magnetic suction support according to claim 2, wherein the support (2) is formed by combining an upper support (23) and a lower support (22), the support magnetic suction structure (21) is fixed on the lower support (22), the upper support (23) has upper support magnetic suction holes (24) matched with the support magnetic suction structures (21) in shape and position, and the support magnetic suction structure (21) penetrates through the upper support magnetic suction hole (24) when the upper support (23) and the lower support (22) are combined.

5. The fan with a magnetic suction support according to claim 3, wherein the support (2) is formed by combining an upper support (23) and a lower support (22), the support magnetic suction structure (21) is fixed on the lower support (22), the upper support (23) has upper support magnetic suction holes (24) matched with the support magnetic suction structures (21) in shape and position, and the support magnetic suction structure (21) penetrates through the upper support magnetic suction hole (24) when the upper support (23) and the lower support (22) are combined.

6. The fan with a magnetic suction support according to claim 4, wherein the support magnetic suction structure (21) is a convex-shaped sheet, and the support (2) is a hollow rectangular structure.

7. The fan with a magnetic suction support according to claim 5, wherein the support magnetic suction structure (21) is a convex-shaped sheet, and the support (2) is a hollow rectangular structure.

8. The fan with a magnetic suction support according to claim 6, wherein the support (2) is disposed with at least four support screw holes (26), the water-cooled row (3) is disposed with water-cooled row screw holes (31) corresponding to the support screw holes (26), the support (2) is arranged with support screws (27), and the support screws (27) penetrate through the support screw holes (26) and are fixed on the water-cooled row screw holes (31).

9. The fan with a magnetic suction support according to claim 7, wherein the support (2) is disposed with at least four support screw holes (26), the water-cooled row (3) is disposed with water-cooled row screw holes (31) corresponding to the support screw holes (26), the support (2) is arranged with support screws (27), and the support screws (27) penetrate through the support screw holes (26) and are fixed on the water-cooled row screw holes (31).

10. The fan with a magnetic suction support according to claim 2, wherein the fan (1) comprises a fan base (13) and a fan surface cover (12), the fan magnetic suction structures (11) are fixed on the fan surface cover (12), the fan base (13) has fan base magnetic suction holes (14) matched with the fan magnetic suction structures (11) in shape and position, and the fan magnetic suction structures (11) penetrate through the fan base magnetic suction holes (14) when the fan base (13) and the fan surface cover (12) are combined.

11. The fan with a magnetic suction support according to claim 3, wherein the fan (1) comprises a fan base (13) and a fan surface cover (12), the fan magnetic suction structures (11) are fixed on the fan surface cover (12), the fan base (13) has fan base magnetic suction holes (14) matched with the fan magnetic suction structures (11) in shape and position, and the fan magnetic suction structures (11) penetrate through the fan base magnetic suction holes (14) when the fan base (13) and the fan surface cover (12) are combined.

12. The fan with a magnetic suction support according to claim 1, wherein the support (2) is arranged with an electro-conductive interface (4), the support (2) is arranged with at least one support electro-conductive contact (28), and the fan (1) is arranged with a fan electro-conductive contact (15) matched with the support electro-conductive contact (28).

13. The fan with a magnetic suction support according to claim 1, wherein the support (2) is arranged with integrally formed L-shaped support fasteners (29), and the fan (1) is disposed with fan fastener holes (16) matched with the support fasteners (29).
